(19) United States
(12) Patent Application Publication
(10) Pub. No.: US 2025/0178904 A1
(43) Pub. Date: Jun. 5, 2025

(54) PIEZOELECTRIC MATERIAL AND PIEZOELECTRIC ELEMENT

(71) Applicant: HIROSHIMA UNIVERSITY, Higashihiroshima-shi, Hiroshima (JP)

(72) Inventors: Sadafumi NISHIHARA, Higashihiroshimashi, Hiroshima (JP); Hidetoshi KURIHARA, Higashihiroshimashi, Hiroshima (JP); Chisato ITO KATO, Higashihiroshimashi, Hiroshima (JP); Masaru FUJIBAYASHI, Higashihiroshimashi, Hiroshima (JP)

(73) Assignee: HIROSHIMA UNIVERSITY, Higashihiroshima-shi, Hiroshima (JP)

(21) Appl. No.: 18/842,846

(22) PCT Filed: Mar. 2, 2023
(86) PCT No.: PCT/JP2023/007762

§ 371 Date: Oct. 4, 2024

(30) Foreign Application Priority Data
Mar. 3, 2022 (JP) 2022-032652

(51) Int. Cl. C01B 25/37; H10N 30/857

(52) U.S. Cl. CPC C01B 25/37; H10N 30/857; C01P 2002/77; C01P 2006/40

(57) ABSTRACT

A piezoelectric material contains a single-molecule electret, and the single-molecule electret is a molecule including a cluster skeleton 100 having a continuous hole 101 and a plurality of stable ionic sites 102a and 102b separate from each other within the continuous hole and a metal ion M included in at least one of the stable ionic sites and capable of migrating to another one of the stable ionic sites that is hollow, and migration of the metal ion included in the at least one of the stable ionic sites to the other one of the stable ionic sites changes molecular polarization; and the polarization continuously changes by having the metal ion of the single-molecule electret migrate to the other one of the stable ionic sites that is hollow, while pressure is applied.

### TECHNICAL FIELD

The present invention relates to a piezoelectric material and a piezoelectric element.

### BACKGROUND ART

In recent years, environmental power generation has been attracting attention as a power generation method that does not emit carbon dioxide. In contrast to solar power generation, wind power generation, and the like, environmental power generation is a technique that converts energy generated in a surrounding environment into electric power for small-scale power generation.

As such environmental power generation, for example, Patent Document 1 discloses a power generation member that generates power by pressing a piezoelectric element supported by a support member with a pressing member. This method of power generation is called vibration power generation. In vibration power generation, the expansion and contraction of a piezoelectric member caused by vibration energy create a charge imbalance within the piezoelectric member, thereby generating electrical energy.

### CITATION LIST

### Patent Documents

Patent Document 1: Japanese Unexamined Patent Publication No. 2010⁻¹⁵³⁷⁷⁷

### SUMMARY OF THE INVENTION

### Technical Problem

The piezoelectric member in the power generation member disclosed in Patent Document 1 only generates electrical energy when expanding or contracting. In other words, such a piezoelectric member cannot produce a continuous flow of current unless it is constantly subjected to vibration energy.

Traditionally, a ferroelectric material has often been used as a piezoelectric material. The ferroelectric material has an electric dipole in a crystal, and the direction and magnitude of polarization of the electric dipole are controlled by application of an electric field.

On the other hand, there are single-molecule electrets which exhibit ferroelectric properties and behavior with a single molecule. The ferroelectric properties and behavior refer to the manifestation of P-E hysteresis and spontaneous polarization. Although the single-molecule electret exhibits ferroelectric properties, there are no findings as to its piezoelectricity.

Given the above circumstances, the present disclosure is made, and it is an object of the present disclosure to provide a piezoelectric material and a piezoelectric element capable of producing a continuous flow of current while pressure is applied thereto, by adopting a single-molecule electret as the piezoelectric material.

### Solution to the Problem

To achieve the above object, a piezoelectric material disclosed herein contains
a single-molecule electret, and
the single-molecule electret is a molecule comprising a cluster skeleton having a continuous hole and a plurality of stable ionic sites separate from each other within the continuous hole and a metal ion included in at least one of the stable ionic sites and capable of migrating to another one of the stable ionic sites that is hollow, and migration of the metal ion included in the at least one of the stable ionic sites to the other one of the stable ionic sites changes molecular polarization; and
the polarization continuously changes by having the metal ion of the single-molecule electret migrate to the other one of the stable ionic sites that is hollow, while pressure is applied.

### Advantages of the Invention

According to the present disclosure, it is possible to provide a piezoelectric material and a piezoelectric element capable of producing a continuous flow of current, even without continuous application of vibration energy, as long as pressure is being applied thereto.

### BRIEF DESCRIPTION OF THE DRAWINGS

FIG. 1 is a schematic plan view showing a molecular structure of a single-molecule electret, according to Examples 1 and 2.

FIG. 2 is a schematic side view showing a molecular structure of a single-molecule electret, according to Examples 1 and 2.

FIG. 3 is a schematic side view of a piezoelectric element.

FIG. 4 is a graph showing a scheme of piezoelectricity measurement.

FIG. 5 is a graph showing variation in a current of the piezoelectric element using the single-molecule electret, according to Example 1.

FIG. 6 is a graph showing variation in a current of the piezoelectric element using the single-molecule electret, according to Example 2.

FIG. 7 is a schematic plan view showing a molecular structure of a single-molecule electret, according to Example 3.

FIG. 8 is a schematic side view showing a molecular structure of a single-molecule electret, according to Example 3.

FIG. 9 is a graph showing variation in current of the piezoelectric element using the single-molecule electret, according to Example 3.

FIG. 10 is an exemplary circuit diagram used for evaluating the charging/discharging characteristics of the piezoelectric element.

FIG. 11 is a graph showing evaluation results of the charging characteristic of the piezoelectric element under vacuum.

FIG. 12 is a graph showing a method of evaluating the charging characteristic of the piezoelectric element.

FIG. 13 is a schematic diagram showing a method of integrating ITh, enlarging X portion in FIG. 12.

FIG. 14 is a graph showing evaluation results of the discharging characteristic of the piezoelectric element under vacuum.

FIG. 15 is a graph showing evaluation results of the discharging characteristic of the piezoelectric element under vacuum.

FIG. 16 is a graph showing evaluation results of the discharging characteristic of the piezoelectric element under vacuum.

FIG. 17 is a graph showing evaluation results of the charging characteristic of the piezoelectric element under vacuum.

FIG. 18 is a graph showing evaluation results of the discharging characteristic of the piezoelectric element under atmospheric pressure.

FIG. 19 is a graph showing evaluation results of the charging characteristic of the piezoelectric element under atmospheric pressure.

FIG. 20 is a graph showing evaluation results of the discharging characteristic of the piezoelectric element to which pressure is applied under atmospheric pressure.

FIG. 21 is a graph showing evaluation results of the discharging characteristic of the piezoelectric element to which pressure is applied under atmospheric pressure.

FIG. 22 is a graph showing evaluation results of the discharging characteristic of the piezoelectric element to which pressure is applied under atmospheric pressure.

FIG. 23 is a schematic plan view showing another exemplary molecular structure of a single-molecule electret.

FIG. 24 is a schematic side view showing another exemplary molecular structure of a single-molecule electret.

FIG. 25 is a schematic plan view showing another exemplary molecular structure of a single-molecule electret.

FIG. 26 is a schematic plan view showing another exemplary molecular structure of a single-molecule electret.

FIG. 27 is a schematic side view showing another exemplary molecular structure of a single-molecule electret.

FIG. 28 is a schematic plan view showing another exemplary molecular structure of a single-molecule electret.

FIG. 29 is a schematic side view showing another exemplary molecular structure of a single-molecule electret.

FIG. 30 is a schematic plan view showing another exemplary molecular structure of a single-molecule electret.

FIG. 31 is a schematic side view showing another exemplary molecular structure of a single-molecule electret.

FIG. 32 is a schematic plan view showing another exemplary molecular structure of a single-molecule electret.

FIG. 33 is a schematic side view showing another exemplary molecular structure of a single-molecule electret.

FIG. 34 is a schematic plan view showing another exemplary molecular structure of a single-molecule electret.

FIG. 35 is a schematic side view showing another exemplary molecular structure of a single-molecule electret.

### DESCRIPTION OF EMBODIMENTS

The following describes embodiments in detail, with reference to the attached drawings. The following description of the preferred embodiments is merely illustrative in nature, and may be suitably modified and applied without departing from the spirit of the present invention.

### —Molecular Structure of Single-Molecule Electret—

As an exemplary molecular structure of a single-molecule electret, there is Preyssler-type polyoxometalate (POM). Preyssler-type POM is a molecular metal oxide cluster having a ring-like structure. The Preyssler-type POM is represented by [Mⁿ⁺⊂P₅W₃₀O₁₁₀]⁽¹⁵⁻ⁿ⁾⁻. The P₅W₃₀O₁₁₀ is a cluster skeleton, and Mⁿ⁺ is a metal ion included in the cluster skeleton. In the cluster skeleton of the Preyssler-type POM, there are two stable ionic sites at positions shifted from the center. The ions incorporated into the cluster skeleton are stably held in any of the stable ionic sites. Such a single-molecule electret exhibits P-E hysteresis and spontaneous polarization based on a slow polarization relaxation phenomenon, unlike a mechanism of hysteresis in ferroelectric materials in general.

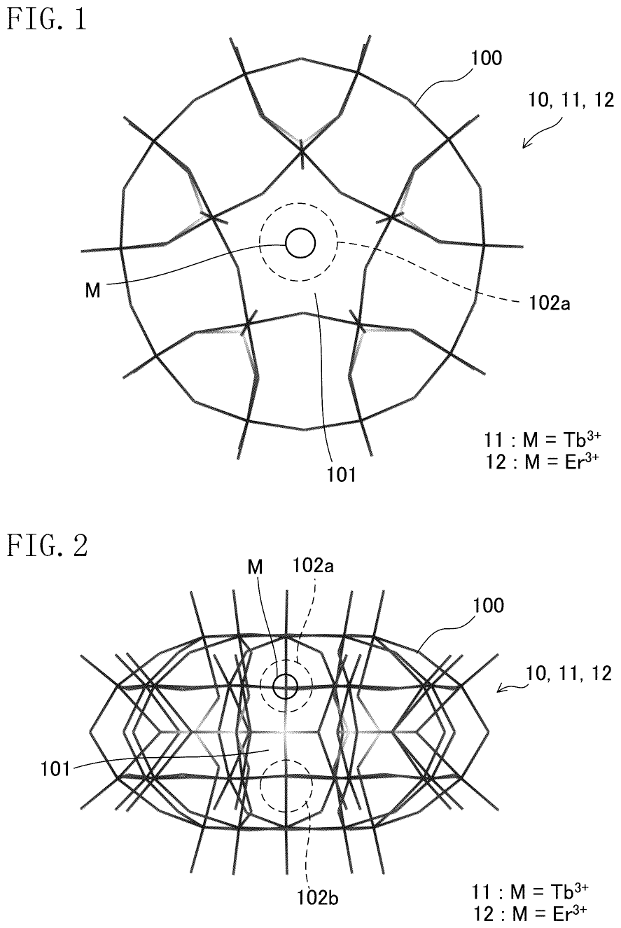

FIG. 1 is a schematic plan view showing a molecular metal oxide cluster that is a molecular structure of a single-molecule electret, according to the present embodiment, and FIG. 2 is a schematic side view of the same. As shown in FIG. 1 and FIG. 2, a single-molecule electret 10 has a cluster skeleton 100 and a metal ion M.

### —Cluster Skeleton—

The cluster skeleton 100 has a plurality of stable ionic sites 102a and 102b separate from each other in a continuous hole 101. In the present embodiment, the cluster skeleton 100 is a polyoxometalate skeleton having two stable ionic sites 102a and 102b in a single continuous hole 101, and is represented by a chemical formula P5W30O110. The cluster skeleton 100 has a substantially oblate spheroidal shape that is short in the direction of its rotation axis and long in the radial direction, has one continuous hole 101 extending along its rotation axis, and has stable ionic sites 102a and 102b for metal ions M on a side of one open end and on a side of the other open end of the continuous hole 101. Of the two stable ionic sites 102a and 102b, one stable ionic site 102a has metal ion M, and the other stable ionic site 102b is hollow. The hollow means an empty state including nothing, no ions or molecules.

### —Metal Ion—

The metal ion M can be included in any one of the stable ionic sites and can migrate to the other hollow stable ionic site. The single-molecule electret exhibits molecular polarization while the metal ion M is included in any one of the stable ionic sites. In the present embodiment, the metal ion M included in the cluster skeleton 100 is capable of migrating between the two stable ionic sites 102a and 102b in the continuous hole 101, and the state in which the metal ion M is included in any of the stable ionic sites 102a and 102b is a stable state. When the metal ion M migrates from one stable ionic site 102a to the other hollow stable ionic site 102b, the metal ion M must overcome the activation energy. X-ray crystallography confirmed that the metal ion M was disordered in the axial direction in the cluster skeleton 100.

In a case of using the cluster skeleton 100, the metal ion M is desirably one selected from the group consisting of a sodium ion (Na⁺) and a lanthanoid ion. For example, the metal ion M is one selected from the group consisting of sodium ions (Na⁺), gadolinium ions (Gd³⁺), terbium ions (Tb³⁺), dysprosium ions (Dy³⁺), holmium ions (Ho³⁺), erbium ions (Er³⁺), thulium ions (Tm³⁺), and ytterbium ions (Yb³⁺). The single-molecule electret 10 including any of the metal ions M exhibits molecular polarization.

Further, the single-molecule electret 10 is also stable in a case of using other metal ions such as calcium ions (Ca²⁺), praseodymium ions (Pr³⁺), neodymium ions (Nd³⁺), samarium ions (Sm³⁺), europium ions (Eu³⁺), lutetium ions (Lu³⁺), cerium ions (Ce⁴⁺, Ce³⁺), ytterbium ions (Y³⁺), bismuth ions (Bi³⁺), uranium ions (U⁴⁺), lanthanum ions (La³⁺), and thorium ions (Th⁴⁺), and has the same ionic radius and electronic characteristics as the lanthanoid ions, and therefore is expected to similar exhibit molecular polarization (see Jorge A. Fernandez, Xavier Lopez, Carles Bo, Coen de Graaf, Evert J. Baerends, Josep M. Poblet, J. Am. Chem. Soc. 2007, 129, 40, 12244-12253).

In a case of using a polyoxometalate skeleton other than the cluster skeleton 100 represented by the chemical formula P₅W₃₀O₁₁₀, other metal ions such as potassium ions (K⁺) can be used as the metal ion M. Further, fullerene or other inclusion compounds capable of including metal ions can be applied as the cluster skeleton. When the cluster skeleton has a plurality of metal ions M, the metal ions M are not limited to one kind, and may be two or more kinds. Various cationic species can be used as the counter cation.

Application of an electric field or pressure to the single-molecule electret 10 causes the metal ion M in the stable ionic site 102a to migrate to the other hollow stable ionic site 102b. This migration of the metal ion M between two stable ionic sites 102a and 102b causes a change in molecular polarization.

The single-molecule electret of the present disclosure is not limited to the above-mentioned Preyssler-type polyoxometalate. The cluster skeleton is not limited to the cluster skeleton 100 including a pair of stable ionic sites 102a and 102b apart from each other in a single continuous hole 101. For example, the cluster skeleton may include a plurality of continuous holes and each of the continuous holes may have a pair of stable ionic sites. Such a cluster skeleton having a plurality of continuous holes can have a plurality of metal ions. The metal ion is included in at least one of the plurality of continuous holes and the plurality of stable ionic sites existing in the continuous hole, and the metal ion migrates to the other hollow stable ionic site, thus causing a change in the molecular polarization. The plurality of continuous holes do not have to be parted from one another by the cluster skeleton. For example, the cluster skeleton may have a single large space in which a plurality of metal ions can migrate, and the plurality of continuous holes may exist as the migration channel of the metal ions. The “continuous holes” shall be broadly interpreted as a passage or a route which connects the stable ionic sites and through which the metal ion migrates.

### EXAMPLE

Next, the following describes specific examples implemented. The present disclosure shall not be limited to these examples, and these examples may be modified and changed in line with the present invention. Such modifications and changes shall not be excluded from the scope of the present invention.

### Example 1

Piezoelectric elements were produced using, as a piezoelectric material, a single-molecule electret 11 (H₁₂₋ₓ(NH₄)ₓ[Tb³⁺⊂P₅W₃₀O₁₁₀]) in which a terbium ion (Tb³⁺) was included as a metal ion M in a cluster skeleton 100 and an ammonium ion (NH₄⁺) was used as a counter cation, and the piezoelectricity thereof was evaluated.

### Synthesis of Single-Molecule Electret 11

33 g of sodium tungstate (Na₂WO₄·2H₂O) was dissolved in 30 mL of water, and 26.5 mL of 85 wt % phosphoric acid (H₃PO₄) was added. The obtained aqueous solution was put into an autoclave, and hydrothermal synthesis was performed at 120° C. for 24 hours. When the autoclave had cooled to the room temperature, 15 mL of water was slowly added to the aqueous solution. Further, 10 g of potassium chloride (KCl) was added to precipitate a solid. The solid was filtered and washed with 2M of potassium acetate (CH₃COOK) and methanol (MeOH). After the solid was dried, recrystallization was performed in 30 mL of warm water to obtain K_{12.5}Na_{1.5}[Na⁺⊂P₅W₃₀O₁₁₀ ]·15H₂O (hereinafter, referred to as a NaPOM).

1 g of NaPOM obtained through the method described above was dissolved in 12 mL of water and heated to 60° C. For the NaPOM, three equivalents of terbium nitrate (Tb(NO₃)₃·6H₂O) were dissolved in 3 mL of water, and a small amount of nitric acid was added. The mixed aqueous solution obtained was put into an autoclave and subjected to hydrothermal synthesis at 180° C. for 72 hours. When the mixed aqueous solution was cooled to the room temperature, 0.5 g of potassium chloride was added to precipitate unreacted NaPOM. Then, 3.5 g of potassium chloride was added to obtain K₁₂[Tb³⁺⊂P₅W₃₀O₁₁₀] salts.

Next, 10 g of K₁₂[Tb³⁺⊂P₅W₃₀O₁₁₀] obtained was dissolved in 200 mL of water, and the solution was passed through a column packed with a strongly acidic cation-exchange resin (DOWEX (registered trade mark)) to obtain an aqueous solution of H₁₂[Tb³⁺⊂P₅W₃₀O₁₁₀]. The aqueous solution of H₁₂[Tb³⁺⊂P₅W₃₀O₁₁₀] was evaporated and dried to solid at 45° C. The H₁₂[Tb³⁺⊂P₅W₃₀O₁₁₀] having been dried to solid was again dissolved in water, and 2.55 g of ammonium chloride NH₄CL was added to recrystallize thereby yielding (H₁₂₋ₓ(NH₄)x[Tb³⁺⊂P₅W₃₀O₁₁₀])·nH₂O.

The crystals obtained were confirmed to be a single-molecule electret 11 including terbium ion (Tb³⁺), through X-ray crystallography.

### Preparation of Piezoelectric Element

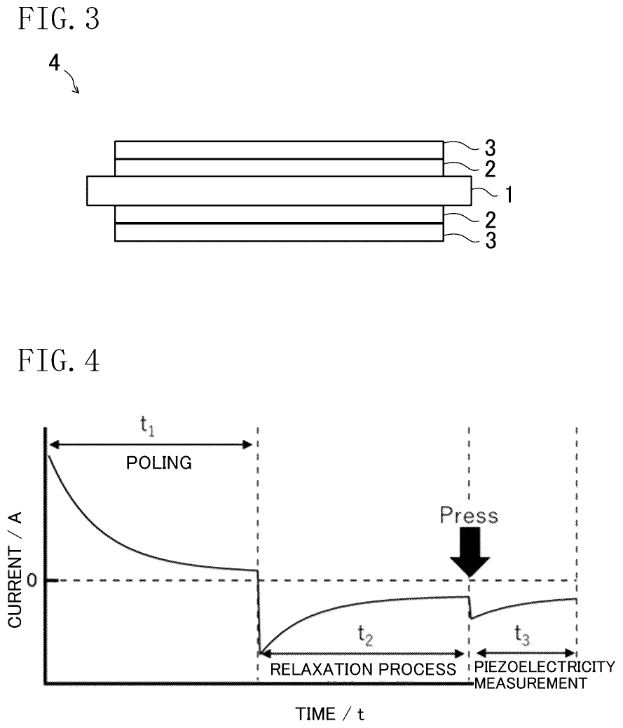

Next, the single-molecule electret 11 obtained was used as a piezoelectric material to produce a piezoelectric element 4 as shown in FIG. 3.

The single crystal of the single-molecule electret obtained according to Example 1 was ground using an agate mortar and a pestle. The crystalline powder was put in a beaker and dried in a vacuum drier at 80° C. The dried crystalline powder was again ground using an agate mortar and a pestle and placed in a tablet press machine. A hydraulic press was used to apply 40 kN to the sample for 10 minutes, followed by 60 kN for 10 minutes to produce a pellet-shaped piezoelectric material with a diameter of 1.3 cm and thickness of 452 μm. Silver paste 2 was applied to both surfaces of this piezoelectric material 1 and dried at the room temperature for 1 hour. Next, to improve contact with an electrode 3, toluene was applied to the surface of the silver paste 2, and the electrode 3 was pressed onto the piezoelectric material 1 from both sides to obtain piezoelectric element 4. Note that, for the electrode 3, a 10 mm diameter SUS disk was used and a single-core cable was used as the lead wire.

As shown in FIG. 3, the piezoelectric element 4 includes a piezoelectric material 1 including the single-molecule electret and the electrode 3 on both sides of the piezoelectric material 1.

### —Measurement of Piezoelectricity—

The piezoelectric element thus obtained was subjected to measurement of its piezoelectricity following the steps described below. For voltage application and current measurement, a high resistance meter (high resistance meter 6517A, produced by Keithley Instruments) was used.

First, to estimate the voltage that can be applied to the piezoelectric material, a low voltage of about 1 V was applied to measure the resistance of the piezoelectric element. The resulting resistance was 1.30×10⁷Ω. Next, a voltage of about 10 V was continuously applied to perform a poling process for aligning the polarization of the single-molecule electret. The current gradually decreased immediately after the voltage was applied. When the current settled to a constant value, the application of voltage was terminated. This poling step corresponds to t₁ in FIG. 4.

A relaxation current associated with polarization reversal of the single-molecule electret (relaxation phenomenon) was observed immediately after voltage application in the poling step ended. Therefore, the current flowed in the opposite direction to that during the poling. To accurately estimate the change in the current value associated with pressure application, the sample was left still until the relaxation phenomenon settled. This relaxation process corresponds to t₂ in FIG. 4.

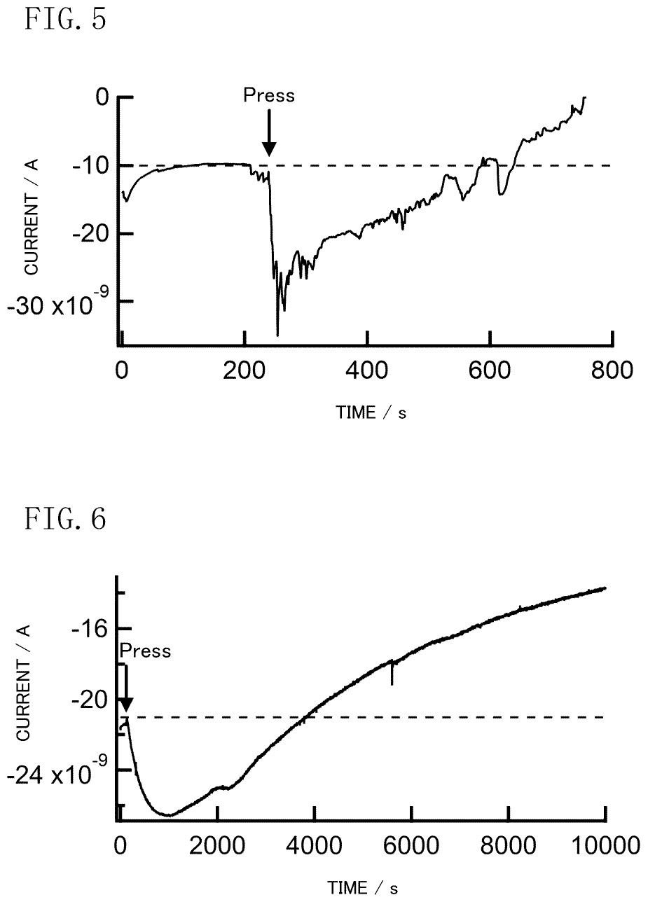

After the relaxation current stabilized, application of constant pressure was continued by clamping the piezoelectric element in a vice via a spring. The “Press” in FIG. 4 and FIG. 5 indicates a point at which application of pressure is started. The pressure applied was estimated to be 12 N (152860 Pa), from the spring displacement and the spring constant. Since the current value was measured while a pressure of 12 N (152860 Pa) was applied under atmospheric pressure (101330 Pa), the piezoelectric element was subjected to a total pressure of 254190 Pa (absolute pressure).

FIG. 5 is a graph showing a measurement result of the current in the piezoelectric element using the single-molecule electret, according to Example 1. As shown in FIG. 5, when the pressure application to the piezoelectric element was continued, the current value rapidly increased immediately after the start of the pressure application and then exponentially decayed upon reaching the maximum value. The measurement result of the current value after the pressure application corresponds to t₃ in FIG. 4.

To describe more in detail the result shown in FIG. 5, the current was in a steady state at about −10 nA, immediately before the pressure was applied. However, when the connection of the terminals was reversed, the current changed to about +10 nA. When pressure application started at Press point during this state, a current of about −35 nA was observed 14 seconds after the start of the pressure application. When application of constant pressure continued, it took approximately 230 seconds for the current value to return from its maximum value (about −35 nA) to the steady state current value (about −10 nA) immediately before the pressure was applied. The piezoelectric material of Example 1 continued to change polarization for approximately 244 seconds from the start of pressure application, and the piezoelectric element of Example 1 produced a continuous flow of current for 244 seconds or more from the start of the pressure application.

### Example 2

Next, piezoelectric elements were produced using, as a piezoelectric material, a single-molecule electret 12 in which an erbium ion (Er³⁺) was included as a metal ion M in a cluster skeleton 100 and a potassium ion (K⁺) was used as a counter cation, and the piezoelectricity thereof was evaluated.

The single-molecule electret 12 was synthesized in the same way as in the above-described Example 1, except that erbium nitrate (Er(NO₃)₃·5H₂O) was used instead of terbium nitrate for NaPOM. A piezoelectric element using the single-molecule electret 12 was created as in Example 1 and current measurement was conducted in the similar manner. For the measurement, a pellet of 1.3 cm in diameter and 321 μm in thickness was used. The resistance between the electrodes measured at 1 V was 3.36×107Ω.

FIG. 6 is a graph showing a measurement result of the current in the piezoelectric element using the single-molecule electret, according to Example 2. As shown in FIG. 6, when the pressure application to the piezoelectric element was continued, the current value rapidly increased immediately after the start of the pressure application and then exponentially decayed upon reaching the maximum value.

To describe more in detail the result shown in FIG. 6, the current was in a steady state at about −21 nA, immediately before the pressure was applied. When pressure application started at Press point during this state, a current of about −26.7 nA was observed 1010 seconds after the start of the pressure application. When application of constant pressure continued, it took approximately 3780 seconds for the current value to return from its maximum value (about −26.7 nA) to the steady state current value (about −21 nA) immediately before the pressure was applied. The piezoelectric material of Example 2 continued to change polarization for approximately 4790 seconds from the start of pressure application, and the piezoelectric element of Example 2 produced a continuous flow of current for 4790 seconds or more from the start of the pressure application.

### Example 3

Next, piezoelectric elements were produced using, as a piezoelectric material, a single-molecule electret 13 (K₂₄Li₅H₇[K⁺₄⊂P₅W₄₈O₁₈₄]) in which a potassium ion (K⁺) was included as a metal ion M in a cluster skeleton 130 having eight stable ionic sites and a lithium ion (Li⁺) was used as a counter cation, and the piezoelectricity thereof was evaluated. For the measurement, a pellet of 1.3 cm in diameter and 549 μm in thickness was used. The resistance between the electrodes measured at 1 V was 1.11×108Ω.

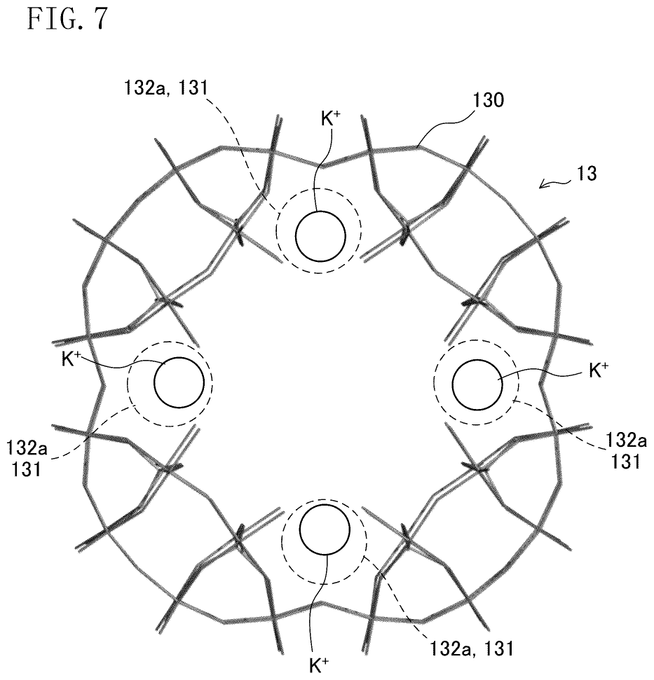

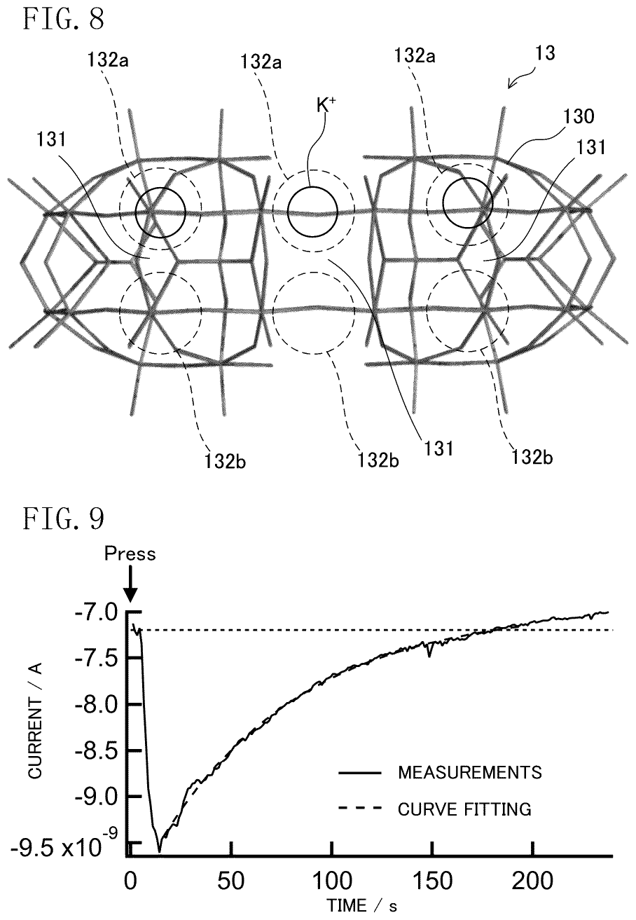

FIG. 7 and FIG. 8 show the single-molecule electret 13 of Example 3. The cluster skeleton 130 has four continuous holes 131 in the circumferential direction, which extend in a direction parallel to its rotation axis. The continuous hole 131 has stable ionic sites 132a and 132b on a side of one open end and on a side of the other open end, and each continuous hole 131 contains one potassium ion. Each metal ion M is axially delocalized (disordered).

The single-molecule electret 13 was obtained as follows. To 1 L of water with 0.5 mol of lithium chloride (LiCl), 0.5 mol of lithium acetate (CH₃COOLi), and 0.5 mol of acetic acid (CH₃COOH), 28 g of K₁₂H₂P₂W₁₂O₄₈·24H₂O was added. The mixed aqueous solution obtained was left to stand in a sealed flask for one week to obtain K₂₄Li₅H₇[K⁺₄⊂P₅W₄₈O₁₈₄]. A piezoelectric element using the single-molecule electret 13 was created as in Example 1 and current measurement was conducted in the similar manner.

FIG. 9 is a graph showing a measurement result of the current in the piezoelectric element using the single-molecule electret, according to Example 3. In FIG. 9, the solid line shows the result of the actual measurement, and the dotted line shows the result of the fitting described below. As shown in FIG. 9, when the pressure application to the piezoelectric element of Example 3 was continued, the current value rapidly increased immediately after the start of the pressure application and then exponentially lowered upon reaching the maximum value.

To describe more in detail the result shown in FIG. 9, the current was in a steady state at about −7.1 nA, immediately before the pressure was applied. When pressure application started at Press point during this state, a current of about −9.6 nA was observed 9 seconds after the start of the pressure application. When application of constant pressure continued, it took approximately 166 seconds for the current value to return from its maximum value (about −9.6 nA) to the steady state current value (about −7.1 nA) immediately before the pressure was applied. The piezoelectric material of Example 3 continued to change polarization for approximately 175 seconds from the start of pressure application, and the piezoelectric element of Example 3 produced a continuous flow of current for 175 seconds or more from the start of the pressure application.

In FIG. 9, the analysis of the change over time of the current value after reaching the maximum value shows a decay curve that fits the following formula (1).

$$\begin{matrix}[ Mathematical Expression 1 ] & \\ y = {y}_{0} + A exp \{ \frac{- ( t - {t}_{0} )}{{τ}_{1}} \} & ( 1 )\end{matrix}$$

In the above formula (1), y is the current, y₀ and t₀ are constants, A is a coefficient, t is time, and τ₁ is a time constant. The decay curve of the single-molecule electret of Example 3 in FIG. 9 was y₀(A)=−6.96×10⁻⁹, A=−2.47×10⁻⁹, τ(s)=70.6, and t₀=16.5.

As shown in FIG. 5 and FIG. 6, the current values of the single-molecule electrets of Examples 1 and 2 show the same tendency as that shown in FIG. 9. Therefore, if measured values with less noise were obtained for the single-molecule electrets of Example 1 and Example 2, their decay curves can be considered to fit formula (1).

### —Method for Measuring Capacity and Charging/Discharging Characteristics—

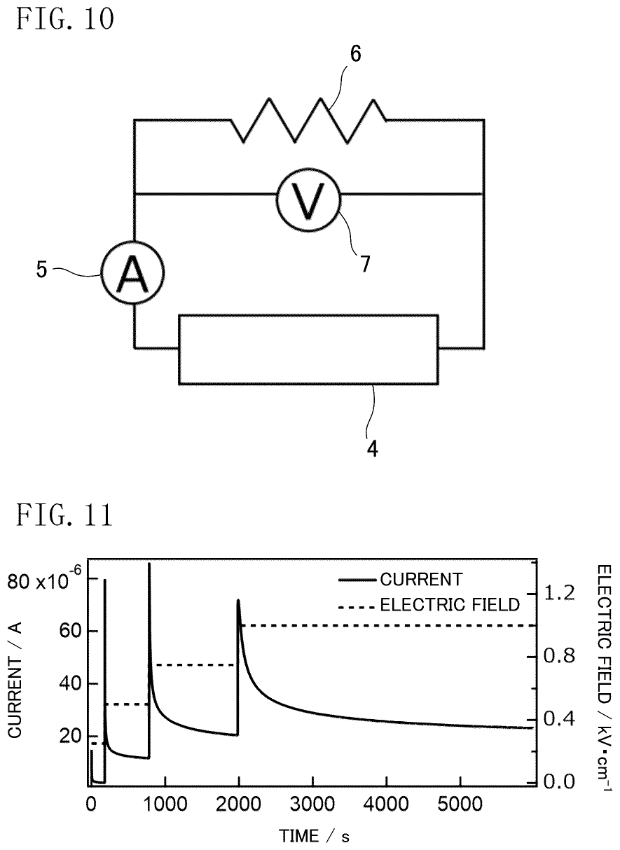

The charging/discharging characteristics were evaluated for the piezoelectric element using the single-molecule electret 11 ((H₁₂₋ₓ(NH₄)ₓ[Tb³⁺⊂P₅W₃₀O₁₁₀])·nH₂O) of Example 1. For the measurement, a high resistance meter (high resistance meter 6517A, produced by Keithley Instruments), a voltmeter (DIGIT MULTIMETER 2110, produced by Keithley Instruments, internal resistance 100 MΩ), and a resistor (1 MΩ) were used. FIG. 10 is an exemplary circuit diagram used for this evaluation. As shown in FIG. 10, the high resistance meter 5 and the resistor 6 were connected in this order in series with the piezoelectric element 4, and a voltmeter 7 was connected in parallel with the resistor 6. Then, the current and voltage were measured. Note that, when a voltage of about 1V was applied to the piezoelectric material under vacuum, the resistivity of the piezoelectric element was measured to be 3.07×10⁷ Ωcm.

### Evaluation 1: Charging Characteristic Under Vacuum and Discharging Characteristic without Application of Pressure Under Vacuum

The charging characteristic under vacuum and the discharging characteristic when discharging is performed without application of pressure under vacuum were evaluated, and the charging/discharging efficiency was determined.

### Evaluation of the Charging Characteristic Under Vacuum

First, the poling process was performed step by step while gradually increasing the electric field applied, under vacuum conditions (1.02×10⁻² Pa). FIG. 11 is a graph showing a method of evaluating the charging characteristic of the piezoelectric element under vacuum. To avoid a large current from flowing in the circuit, the electric field was gradually applied step by step in an order of 0.25 kV/cm for 120 seconds, 0.50 kV/cm for 600 seconds, 0.75 kV/cm for 1200 seconds, and 1.00 kV/cm for 3600 seconds. Normally, the current value increases to its maximum upon switching the voltage applied; however, in this piezoelectric element, a gradual increase in the current was observed at a certain voltage applied. The maximum voltage of the poling process was set to that voltage. The current reached its maximum value immediately after the voltage was applied, and then gradually decreased over time until it settled to a constant value. After the current settled, the application of voltage was ended. FIG. 11 shows a value of the electric field obtained by dividing the actual voltage by the distance between the electrodes. The solid line shows the current value and the dotted line shows the voltage applied as a theoretical value.

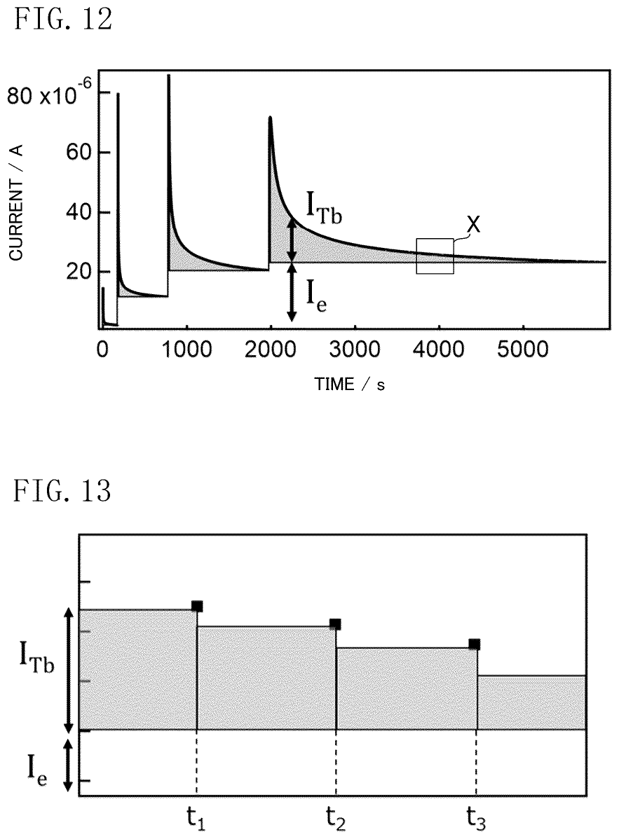

The following describes a method of estimating charging capacity, taking FIG. 12 as an example. FIG. 12 is a graph similar to FIG. 11 and shows a method of evaluating the charging characteristic of the piezoelectric element. Current components flowing during this poling step are classified into a component originating from the migration of encapsulated ions in the single-molecule electret (ITb) and a component of the resistor (Ie). Ie corresponds to the current value when the relaxation current has settled. Therefore, the charging capacity can be estimated by subtracting Ie from the current during the poling and integrating only ITb. Charging capacity is the area of the gray area in FIG. 12. FIG. 13 is a schematic diagram showing a method of integrating ITb, enlarging X portion in FIG. 12. The charging capacity can be derived by integrating the current values from immediately after voltage application till the end of the application, using the following formula (2).

$$C = ( {t}_{2} - {t}_{1} ) \times ITb \qquad ( 2 )$$

t₁ and t₂ represent the time elapsed from the start of the measurement, and ITb indicates the current attributed to the migration of terbium ions at that measurement point.

The charging capacity under vacuum in Evaluation 1 was 267 mAh/L.

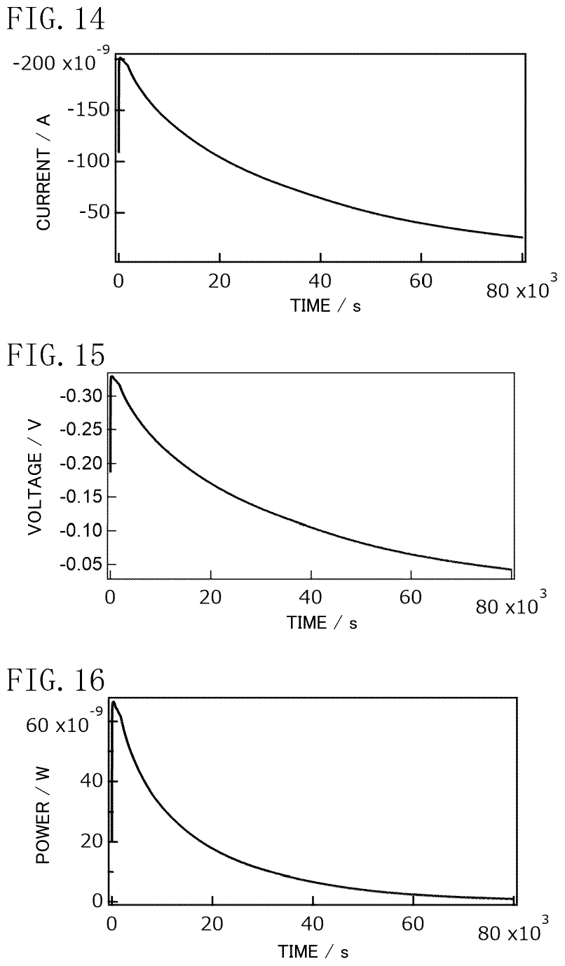

Evaluation of discharging characteristic when pressure is not applied under vacuum. A relaxation current associated with polarization reversal of the single-molecule electret (relaxation phenomenon) was observed immediately after the above-described poling process, and the current flowed in the opposite direction to that during the poling. The results of evaluating the discharge current, voltage and electric power when no pressure is applied under vacuum are shown in FIG. 14, FIG. 15 and FIG. 16.

The current decayed upon reaching the maximum current value, during the discharge. The decay was exponential. The total current when the discharge is completed, i.e., when the time is set to infinity, was calculated from the following fitting.

The change over time of the current value after reaching the maximum value shows a decay curve that fits the following formula (3).

$$\begin{matrix}[ Mathematical Expression 2 ] & \\ y = {A}_{1} exp \{ \frac{- ( t - {t}_{0} )}{{τ}_{1}} \} + {A}_{2} exp \{ \frac{- ( t - {t}_{0} )}{{τ}_{2}} \} & ( 3 )\end{matrix}$$

In the above formula (3), y is the current, to is a constant, A₁ and A₂ are coefficients, t is time, and τ₁ and τ₂ are time constants. The estimated discharge capacity was calculated by integrating the above formula (3) over the number of seconds from the start of measurement to infinity.

In Evaluation 1, the above formula (3) was such that to was 113s, A₁ was −4.35×10⁻⁸, A₂ was −1.64×10⁻⁷, τ₁ was 6579s, τ₂ was 43165s, and the discharge capacity was 82.3 mAh/L.

From the charging capacity of 267 mAh/L calculated using the above formula (2) and the discharge capacity calculated using the formula (3), the charging/discharging efficiency of Evaluation 1, which was subjected to poling process under vacuum and discharged under vacuum, was 30.8%.

### Evaluation 2: Charging Characteristic Under Vacuum and Discharging Characteristic without Application of Pressure Under Atmospheric Pressure

The charging characteristic under vacuum and the discharging characteristic when discharging is performed without application of pressure under atmospheric pressure were evaluated, and the charging/discharging efficiency was determined. Note that, for Evaluation 2, the same circuit as that shown in FIG. 10, except in that the voltmeter and the resistor were omitted was used.

### Evaluation of the Charging Characteristic Under Vacuum

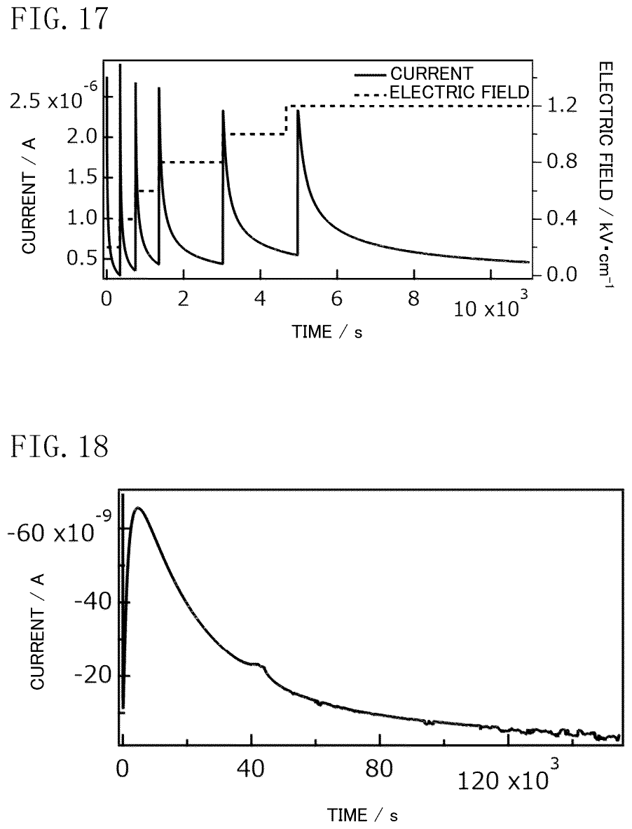

First, the poling process was performed step by step while gradually increasing the electric field applied, under vacuum conditions (1.02×10⁻² Pa). FIG. 17 is a graph showing a method of evaluating the charging characteristic of the piezoelectric element under vacuum. To avoid a large current from flowing in the circuit, the electric field was gradually applied step by step in an order of 0.2 kV/cm for 340 seconds, 0.4 kV/cm for 405 seconds, 0.6 kV/cm for 610 seconds, 0.8 kV/cm for 1660 seconds, 1.0 kV/cm for 1650 seconds, and 1.2 kV/cm for 6330 seconds. As in Evaluation 1, a gradual increase in the current was observed at a certain voltage applied. The maximum voltage of the poling process was set to that voltage. The current reached its maximum value immediately after the voltage was applied, and then gradually decreased over time until it settled to a constant value. After the current settled, the application of voltage was ended. FIG. 17 shows a value of the electric field obtained by dividing the actual voltage by the distance between the electrodes. The solid line shows the current value and the dotted line shows the voltage applied as a theoretical value.

The charging capacity was calculated from the above formula (2) as in Evaluation 1. The charging capacity under vacuum in Evaluation 2 was 64.2 mAh/L.

Evaluation of discharging characteristic when pressure is not applied under atmospheric pressure.

A relaxation current associated with polarization reversal of the single-molecule electret (relaxation phenomenon) was observed immediately after the above-described poling process, and the current flowed in the opposite direction to that during the poling. The result of evaluating the discharge current when no pressure is applied under atmospheric pressure (101330 Pa) is shown in FIG. 18.

The current decayed upon reaching the maximum current value, during the discharge. The decay in the current value was exponential. The total current when the discharge is completed (when the time is set to infinity), was calculated from the above formula (3) similarly to Evaluation 1.

The discharge capacity under atmospheric pressure in Evaluation 2, calculated with the above formula (3), was 23.0 mAh/L. From the charging capacity of 64.2 mAh/L calculated using the above formula (2) and this discharge capacity, the charging/discharging efficiency of Evaluation 2, which was subjected to poling process under vacuum and discharged under atmospheric pressure, was 35.8%.

### Evaluation 3: Charging Characteristic Under Atmospheric Pressure and Discharging Characteristic with Application of Pressure Under Atmospheric Pressure

The charging characteristic under atmospheric pressure (101330 Pa) and the discharging characteristic when discharging is performed with the application of a pressure 12N (152860 Pa) under atmospheric pressure (101330 Pa) were evaluated, and the charging/discharging efficiency was determined. During the discharge, the piezoelectric element was subjected to a pressure of 12 N in addition to atmospheric pressure, resulting in application of a total pressure of 254190 Pa as the absolute pressure.

### Evaluation of the Charging Characteristic Under Atmospheric Pressure

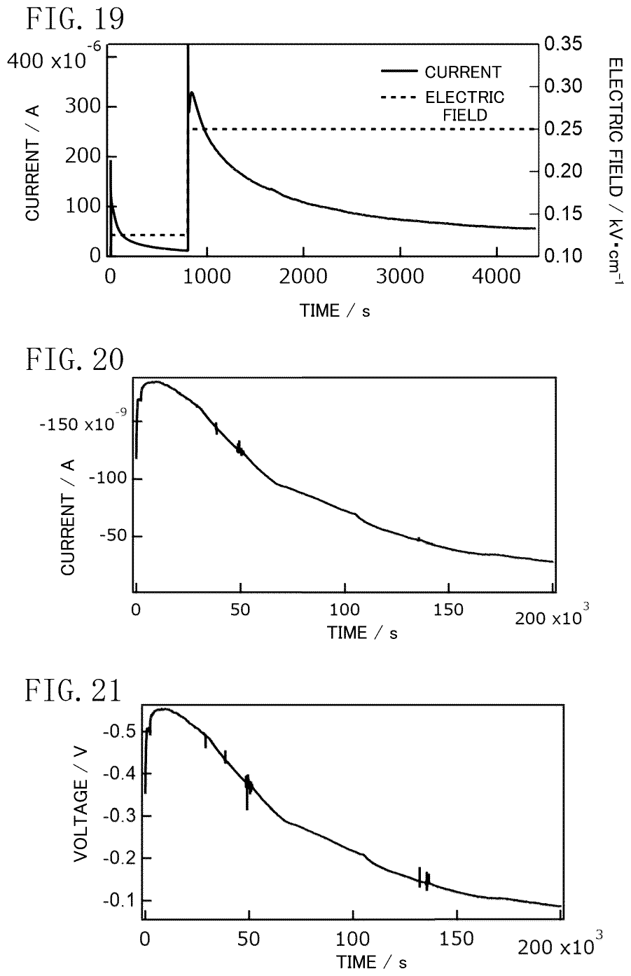

First, the poling process was performed step by step while gradually increasing the electric field applied, under atmospheric pressure (101330 Pa). FIG. 19 is a graph showing a method of evaluating the charging characteristic of the piezoelectric element under atmospheric pressure. To avoid a large current from flowing in the circuit, the electric field was gradually applied step by step in an order of 0.125 kV/cm for 800 seconds, and 0.25 kV/cm for 3600 seconds. As in Evaluation 1 and Evaluation 2, a gradual increase in the current was observed at a certain voltage applied. The maximum voltage of the poling process was set to that voltage. The current reached its maximum value immediately after the voltage was applied, and then gradually decreased over time until it settled to a constant value. After the current settled, the application of voltage was ended. FIG. 19 shows a value of the electric field obtained by dividing the actual voltage by the distance between the electrodes. The solid line shows the current value and the dotted line shows the voltage applied as a theoretical value.

The charging capacity was calculated from the above formula (2) as in Evaluation 1 and Evaluation 2. The charging capacity under atmospheric pressure in Evaluation 3 was 1280 mAh/L.

Evaluation of discharging characteristic when pressure is applied under atmospheric pressure.

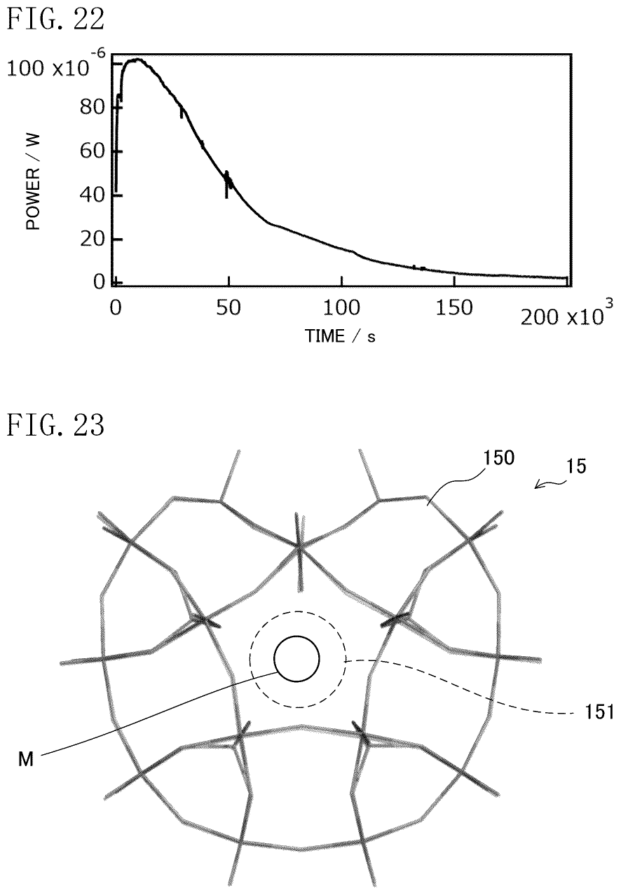

A relaxation current associated with polarization reversal of the single-molecule electret (relaxation phenomenon) was observed immediately after the above-described poling process, and the current flowed in the opposite direction to that during the poling. The results of evaluating the discharge current, voltage and electric power when pressure was applied under atmospheric pressure are shown in FIG. 20, FIG. 21 and FIG. 22.

Discharging Characteristic while Pressure is Applied and Evaluation Method.

The pressure applied under atmospheric pressure was estimated from the relation between the spring displacement and the spring constant. The applied pressure was set to 12 N (152860 Pa) by clamping the spring and the measurement sample with a vice. Under atmospheric pressure, pressure was applied to the piezoelectric element 2400 seconds after the discharge started, and the discharge current and voltage were measured, and the electric power from their product. As shown in FIG. 20, FIG. 21, and FIG. 22, the current value rapidly increased immediately after the start of the pressure application and then exponentially decayed upon reaching the maximum value.

The current decayed upon reaching the maximum current value, during the discharge. The decay in the current value was exponential. The total current when the discharge is completed (when the time is set to infinity), was calculated from the above formula (3) similarly to Evaluation 1 and Evaluation 2.

In Evaluation 3, the above formula (3) was such that t₀ was 0s, A₁ was −1.07×10⁻⁷, A₂ was −1.09×10⁻⁷, τ₁ was 109210s, t₂ was 107180s, and the discharge capacity was 655 mAh/L.

From the charging capacity of 1280 mAh/L calculated using the above formula (2) and the discharge capacity calculated from the above formula (3), the charging/discharging efficiency of Evaluation 3, which was subjected to poling process under atmospheric pressure and discharged under atmospheric pressure while pressure was applied under atmospheric pressure, was 51.2%.

As described above, the piezoelectric element using the single-molecule electret disclosed herein as the piezoelectric material exhibits an exponential decrease in the current value upon reaching the maximum value when pressure is continuously applied. In other words, this piezoelectric element can produce a continuous flow of current as long as pressure is applied. This is attributed to the fact that the single-molecule electret used as the piezoelectric material of the present disclosure is able to continuously change the polarization while pressure is applied.

Based on the results in Evaluation 1 to Evaluation 3 described above, the piezoelectric element using the single-molecule electret of the present disclosure as its piezoelectric material has shown that it is capable of producing a continuous flow of current even with a slight pressure in the vacuum state (1.02×10⁻² Pa). Application of pressure that is higher than the vacuum state (1.02×10⁻² Pa) improves the charging/discharging efficiency. For example, under atmospheric pressure (101330 Pa), a pressure greater than that under the vacuum state (1.02×10⁻² Pa) is applied without artificially applying pressure, and under atmospheric pressure (101330 Pa), a much higher charging/discharging efficiency than that under the vacuum state (1.02×10⁻² Pa) was shown. Artificial application of additional pressure under atmospheric pressure resulted in a higher charging/discharging efficiency than charging/discharging of the piezoelectric element simply left under atmospheric pressure.

The pressure applied to the piezoelectric element disclosed herein is at least 1.02×10⁻² Pa or higher, preferably atmospheric pressure (101330 Pa) or higher, and more preferably the absolute pressure of 254190 Pa or higher. Theoretically, as the pressure is increased, the charging/discharging efficiency is expected to hit the ceiling at a certain pressure. Based on the above evaluation results, it is believed that the upper limit of the pressure is 860000 Pa in terms of absolute pressure. Application of pressure greater than 860000 Pa to the piezoelectric element disclosed herein is not realistic, taking into consideration of the energy efficiency.

### Other Molecular Structure of Single-Molecule Electret—

Each of the above examples deals with a piezoelectric material having a skeleton shown in FIG. 1, FIG. 2, FIG. 7, or FIG. 8. However, the piezoelectric material is not limited to this. Assuming that a single-molecule electret having continuous holes and stable ionic sites separately in the continuous holes exhibits molecular polarization similar to that in the Preyssler-type POM, when the metal ions are delocalized (disordered) within the cluster skeleton, such a single-molecule electret can be used as a piezoelectric material in the piezoelectric element as in the above-described examples, and is believed to exhibit the similar characteristics. Note that delocalization herein refers to dynamic disorder.

FIG. 23 to FIG. 35 are each a schematic diagram of a single-molecule electret having a polyoxometalate skeleton as the cluster skeleton, similarly to Examples 1 to 3, where delocalization of metal ions M within the cluster skeleton is confirmed. Although FIG. 23 to FIG. 35 show a state in which the metal ions M are accommodated in any of the stable ionic sites, for the sake of convenience, the metal ions M are actually delocalized between the stable ionic sites.

A single-molecule electret 15 shown in FIG. 23 and FIG. 24 has a cluster skeleton 150 that is a polyoxometalate skeleton having a heart-like shape formed by partially denting the cluster skeleton 100. This cluster skeleton 150 has a substantially oblate spheroidal shape that is short in the axial direction and long in the radial direction as in the cluster skeleton 100, and has a continuous hole 151 extending along the rotation axis. The continuous hole 151 has stable ionic sites 152a and 152b on a side of one open end and a side of the other open end, and a single potassium ion (K⁺) is included in the continuous hole 151 as the metal ion M. The chemical formula of this single-molecule electret 15 is represented by [K+⊂{W₂CoO₈(H₂O)₂}(P₂W₁₂O₄₆)₂]¹⁹⁻. Since potassium ions delocalize in the axial direction, a physical property similar to the single-molecule electrets 11 to 13 is expected.

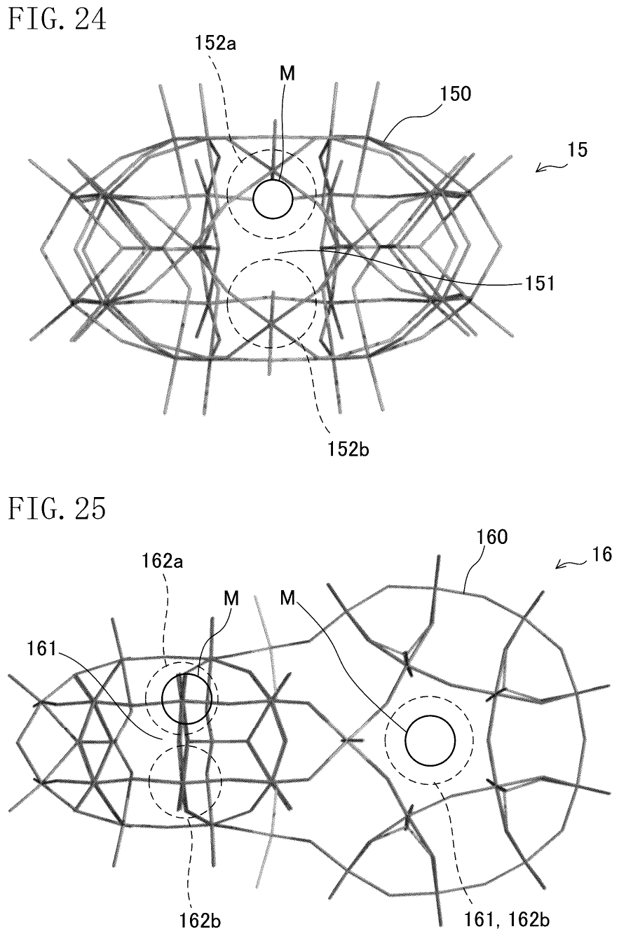

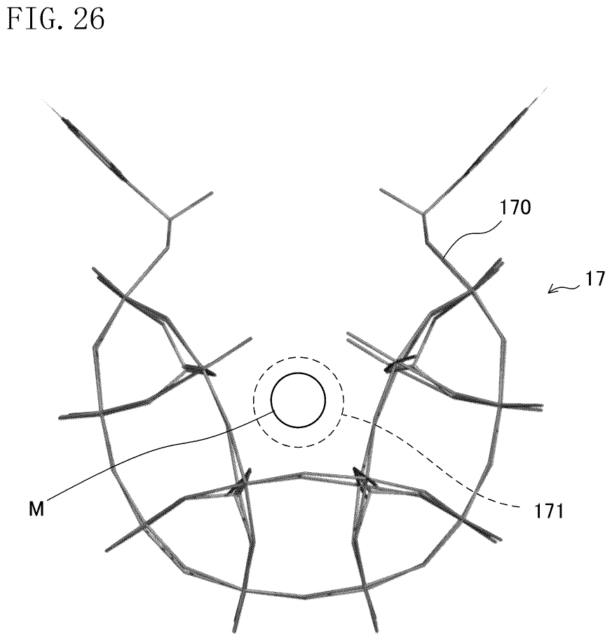

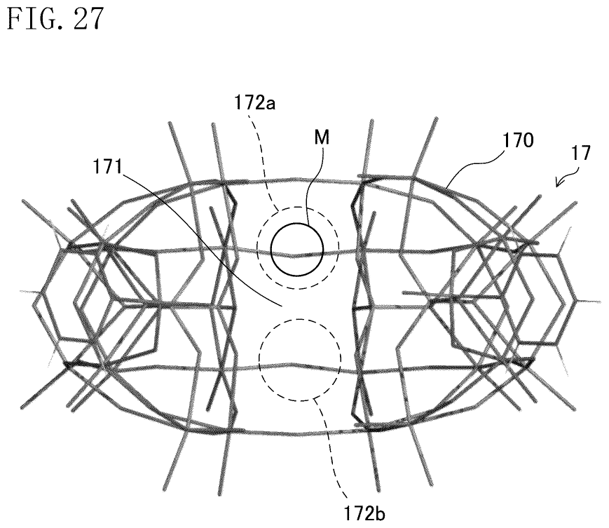

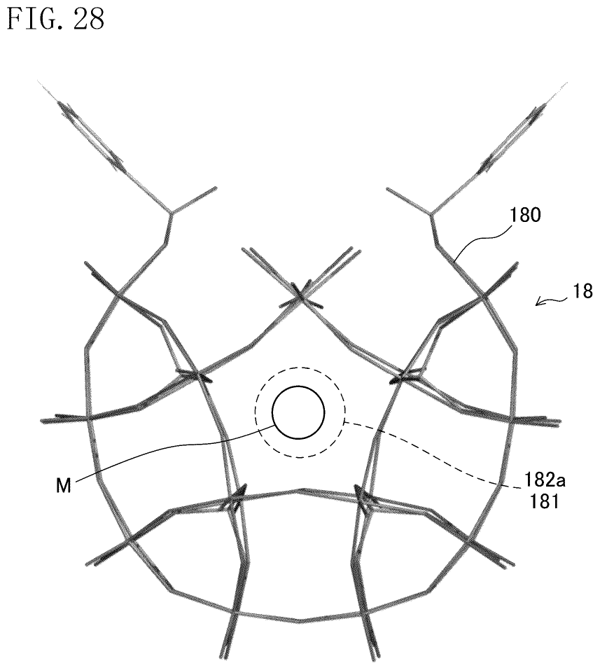

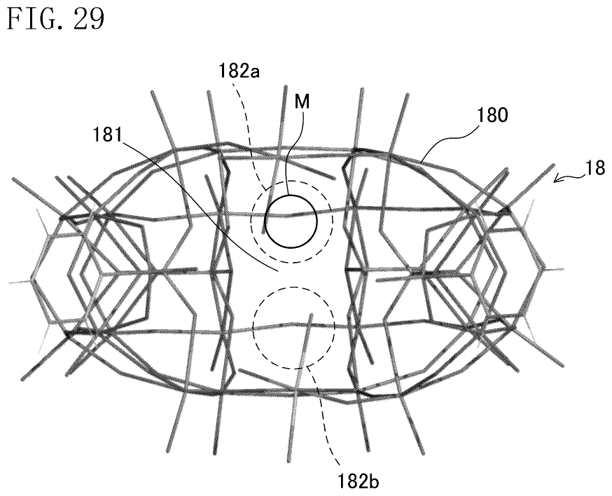

A single-molecule electret 16 shown in FIG. 25 has a cluster skeleton 160 that is a polyoxometalate skeleton having a shape such that two cluster skeletons 100 are joined substantially perpendicular to each other. This cluster skeleton 160 has two continuous holes 161 extending in directions substantially perpendicular to each other. The continuous holes 161 each has stable ionic sites 162a and 162b on a side of one open end and on a side of the other open end, and each continuous hole 161 contains a single metal ion M. The chemical formula of this single-molecule electret 16 is represented by [{Sn(CH₃)₂}₄H₂(M⁺⊂P₄W₂₄O₉₂)₂]²⁶⁻. Since the metal ion M delocalize in two directions substantially perpendicular to each other, the metal ions M are believed to exhibit a physical property similar to the single-molecule electrets 11 to 13.

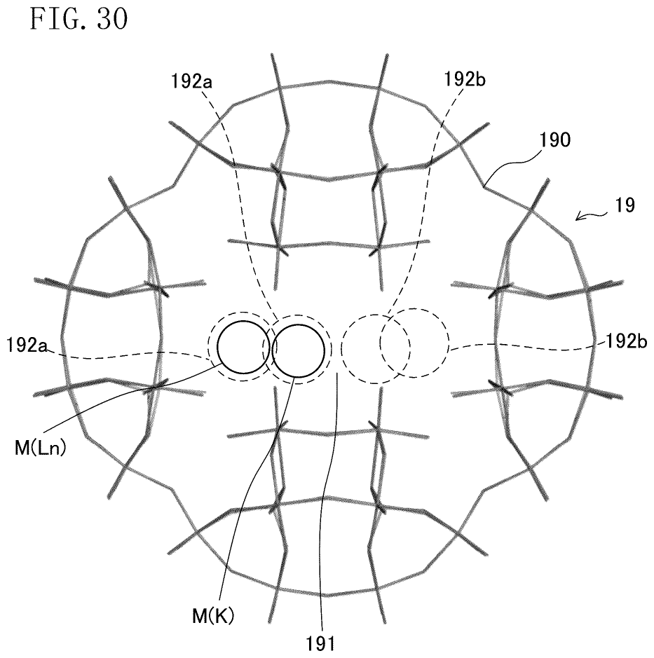

A single-molecule electret 17 shown in FIG. 26 and FIG. 27 has a cluster skeleton 170 that is a polyoxometalate skeleton having a shape such that a part of the cluster skeleton 100 is cleaved and a phenyl group is attached to its terminal. This cluster skeleton 170 has a single continuous hole 171 as in the above-described cluster skeleton 100. The continuous hole 171 has stable ionic sites 172a and 172b on a side of one open end and on a side of the other open end, and the continuous hole 171 contains a single metal ion M. The chemical formula of this single-molecule electret 17 is represented by [M⁺⊂(PhPO)₂P₄W₂₄O₉₂]¹⁵⁻or [M⁺⊂(PhAsO)₂P₄W₂₄O₉₂]¹⁵⁻. Since metal ions M delocalize in the axial direction, a physical property similar to the single-molecule electrets 11 to 13 is expected.

A single-molecule electret 18 shown in FIG. 28 and FIG. 29 has a cluster skeleton 180 that is a polyoxometalate skeleton having a shape such that a part of the cluster skeleton 100 is cleaved and a phenyl group is attached to its terminal. This cluster skeleton 180 has a single continuous hole 181 as in the above-described cluster skeleton 100. The continuous hole 181 has stable ionic sites 182a and 182b on a side of one open end and on a side of the other open end, and the continuous hole 181 contains a single metal ion M. The chemical formula of this single-molecule electret 18 is represented by [M⁺⊂{Co(H₂O)₄}₂(PhPO)₂P₄W₂₄O₉₂]⁹⁻. Since metal ions M delocalize in the axial direction, a physical property similar to the single-molecule electrets 11 to 13 is expected.

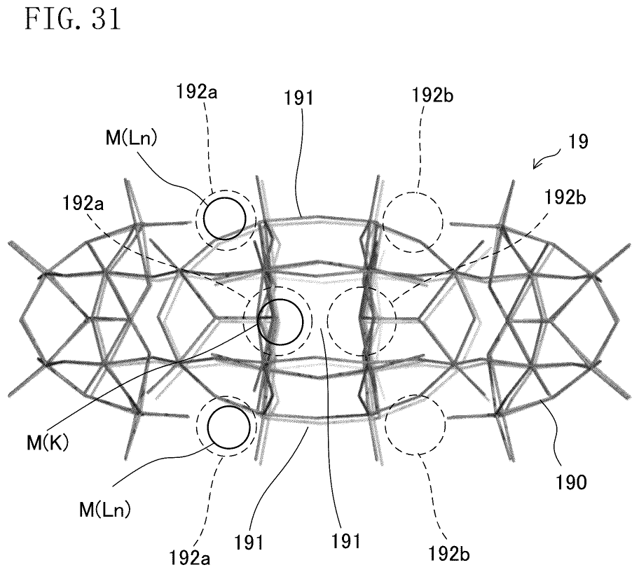

A single-molecule electret 19 shown in FIG. 30 and FIG. 31 has a cluster skeleton 190 that is a polyoxometalate skeleton having a shape such that the cluster skeleton 100 is expanded in the circumferential direction to form a substantially oblate spheroidal shape. The cluster skeleton 190 has three continuous holes 191 in a direction approximately perpendicular to its rotation axis. The three continuous hole 191 are in a single large space within the cluster skeleton 190. The three continuous holes 191 exist as a migration pathway of metal ions M within the large space. Each of the continuous holes 191 has stable ionic sites 192a and 192b on a side of one open end and on a side of the other open end, and each of the continuous holes 191 contains a single metal ion M. The chemical formula of this single-molecule electret 19 is represented by [K⁺⊂{P₅W₄₈O₁₈₄(H₄W₄O₁₂)₂}Ln₂(H₂O)₁₀]²⁵⁻(Ln=La, Ce, Pr, Nd). Specifically, the metal ions M contained in the single-molecule electret 19 are one potassium ion and two lanthanoid ions. Since metal ions M delocalize in a direction substantially perpendicular to the rotation axis, a physical property similar to the single-molecule electrets 11 to 13 is expected.

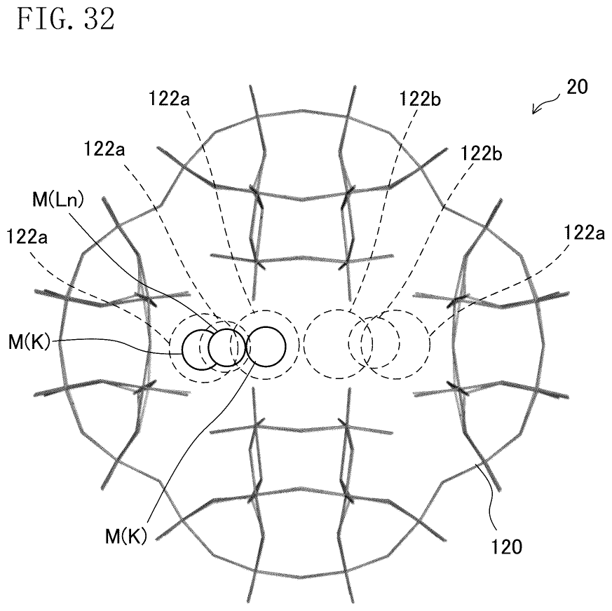

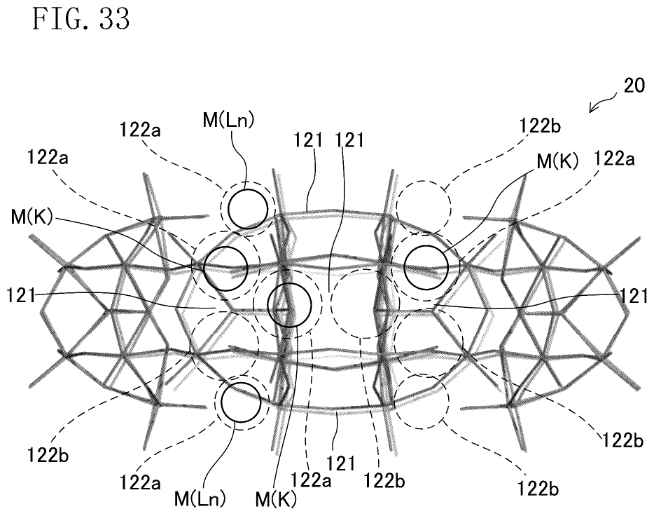

A single-molecule electret 20 shown in FIG. 32 and FIG. 33 has a cluster skeleton 120 that is a polyoxometalate skeleton having a shape such that the cluster skeleton 100 is expanded in the circumferential direction to form a substantially oblate spheroidal shape. The cluster skeleton 120 has five continuous holes 121 in a direction substantially parallel to its rotation axis and a direction substantially perpendicular to its rotation axis. The five continuous holes 121 are in a single large space within the cluster skeleton 120. The five continuous holes 121 exist as a migration pathway of metal ions M within the large space. Each of the continuous holes 121 has stable ionic sites 122a and 122b on a side of one open end and on a side of the other open end, and each of the continuous holes 121 contains a single metal ion M. The chemical formula of this single-molecule electret 20 is represented by [K⁺₃⊂{P₅W₄₈O₁₈₄(H₄W₄O₁₂)₂}Ce₂(H₂O)₁₀]²³⁻. Specifically, the metal ions M contained in the single-molecule electret 20 are three potassium ions and two cerium ions. Since two potassium ions out of the three potassium ions delocalize in the direction substantially parallel to the rotation axis and one potassium ion and the two cerium ions delocalize in the direction substantially perpendicular to the rotation axis, a physical property similar to the single-molecule electrets 11 to 13 is expected.

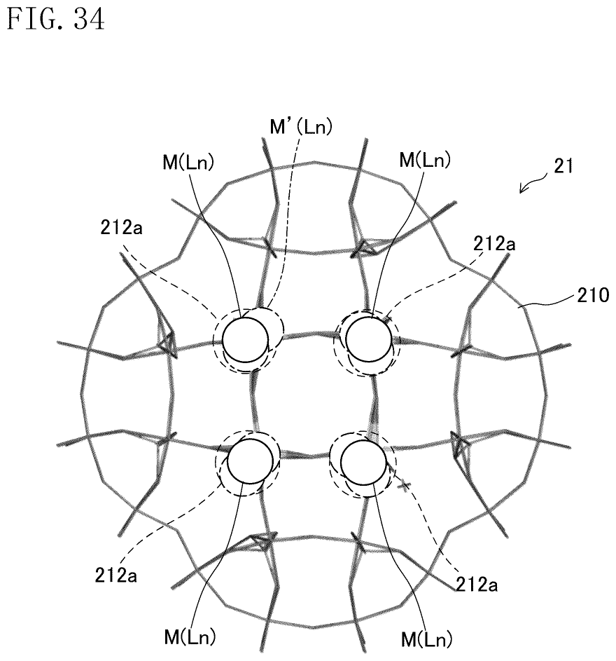

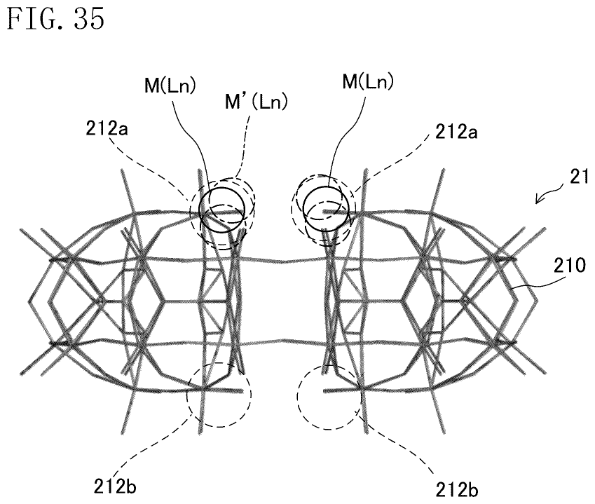

A single-molecule electret 21 shown in FIG. 34 and FIG. 35 has a cluster skeleton 210 that is a polyoxometalate skeleton having a shape such that the cluster skeleton 100 is expanded in the circumferential direction to form a substantially oblate spheroidal shape. The cluster skeleton 210 has four metal ions M (lanthanoid ions), and for each of the metal ions M, has two separate stable ionic sites 212a and 212b. The single-molecule electret 21 has eight stable ionic sites in total, and the four metal ions M randomly delocalize among these eight stable ionic sites. Further, each of the metal ions M further delocalizes in the stable ionic sites 212a and 212b. Therefore, this single-molecule electret 21 is believed to exhibit a physical property similar to the single-molecule electrets 11 to 13, in response to application of a voltage. The chemical formula of this single-molecule electret 21 is represented by {[Ln³⁺₂(μ-OH)₄(H₂O)ₓ]₂H₂₄[P₅W₄₈O₁₈₄]}¹²⁻(Ln=Nd, Sm, Tb).

These single-molecule electrets 15, 16, 17, 18, 19, 20, 21 having a polyoxometalate skeleton are expected to bring about effects similar to those of the above-described single-molecule electrets 11 to 13, because delocalization of the metal ions M between the stable ionic sites is exhibited. Further, the metal ion M is not limited to the ones mentioned above, and other metal ions M are adoptable as long as they exhibit delocalization within the cluster skeleton. Further, various cationic species can also be applied as the counter cation.

### DESCRIPTION OF REFERENCE CHARACTERS

1 Piezoelectric Material
2 Silver Paste
3 Electrodes
4 Piezoelectric Element
5 High Resistance Meter
6 Resistor
7 Voltmeter
11 Single-molecule electret
12 Single-molecule electret
13 Single-molecule electret
100 Cluster Skeleton
101 Continuous hole
102a Stable ionic site
102b Stable ionic site
M Metal Ion

1. A piezoelectric material containing a single-molecule electret, wherein
the single-molecule electret is a molecule comprising a cluster skeleton having a continuous hole and a plurality of stable ionic sites separate from each other within the continuous hole and a metal ion included in at least one of the stable ionic sites and capable of migrating to another one of the stable ionic sites that is hollow, and migration of the metal ion included in the at least one of the stable ionic sites to the other one of the stable ionic sites changes molecular polarization; and
the polarization continuously changes by having the metal ion of the single-molecule electret migrate to the other one of the stable ionic sites that is hollow, while pressure is applied.

2. A piezoelectric element, comprising the piezoelectric material of claim 1 and an electrode, wherein
a continuous flow of current is produced while pressure is applied to the piezoelectric material.

3. The piezoelectric element of claim 2, wherein
the current value exponentially decays upon reaching a maximum value, when constant pressure is continuously applied.

4. The piezoelectric element of claim 3, wherein
the current value while the pressure is applied exhibits a decay curve as indicated by the following formula (1)
$$\begin{matrix}[ Mathematical Expression 1 ] & \\ y = {y}_{0} + A exp \{ \frac{- ( t - {t}_{0} )}{{τ}_{1}} \} & ( 1 )\end{matrix}$$
where, in the above formula (1), y is the current, y₀ and t₀ are constants, A is a coefficient, t is time, and τ₁ is a time constant.

5. The piezoelectric element of claim 4, wherein
the current value while the pressure is applied exhibits a decay curve as indicated by the following formula (2)
$$\begin{matrix}[ Mathematical Expression 2 ] & \\ y = {A}_{1} exp \{ \frac{- ( t - {t}_{0} )}{{τ}_{1}} \} + {A}_{2} exp \{ \frac{- ( t - {t}_{0} )}{{τ}_{2}} \} & ( 2 )\end{matrix}$$
where, in the above formula (2), y is the current, to is a constant, A₁ and A₂ are coefficients, t is time, and τ₁ and τ₂ are time constants.

6. The piezoelectric element of claim 5, wherein
application of pressure that is an atmospheric pressure or higher exhibits a higher charging/discharging efficiency than that in a case of applying no pressure under vacuum.

7. The piezoelectric element of claim 6, wherein
while the pressure is applied, it takes 166 seconds or longer for the current value to return from the maximum value to a value immediately before the start of applying the pressure.

8. The piezoelectric element of any one of claim 2, wherein
the cluster skeleton is a polyoxometalate skeleton.

9. The piezoelectric element of claim 8, wherein
the cluster skeleton is a polyoxometalate skeleton represented by a chemical formula P₅W₃₀O₁₁₀ or P₈W₄₈O₁₈₄.
